(19) United States
(12) Patent Application Publication
(10) Pub. No.: US 2023/0389360 A1
(43) Pub. Date: Nov. 30, 2023

(54) DISPLAY DEVICE

(71) Applicant: Japan Display Inc., Tokyo (JP)

(72) Inventors: Masakazu GUNJI, Tokyo (JP); Jun NITTA, Tokyo (JP)

(73) Assignee: Japan Display Inc., Tokyo (JP)

(21) Appl. No.: 18/450,417

(22) Filed: Aug. 16, 2023

Related U.S. Application Data
(63) Continuation of application No. PCT/JP2022/005126, filed on Feb. 9, 2022.

(30) Foreign Application Priority Data
Feb. 18, 2021 (JP) 2021-024456

(51) Int. Cl. H10K 59/121; H10K 50/18

(52) U.S. Cl. CPC H10K 59/1213; H10K 50/181

(57) ABSTRACT

According to one embodiment, a display device includes a base, a plurality of pixel circuits, an insulating layer, a plurality of apertures, a plurality of display elements and a partition. Each of the display elements includes a lower electrode, an organic layer and an upper electrode. The lower electrode and the organic layer are in contact over an entire surface of the aperture. The organic layer and the upper electrode are in contact over the entire surface of the aperture. The peripheral portion of the lower electrode is covered by the partition.

### CROSS-REFERENCE TO RELATED APPLICATIONS

This application is a Continuation application of PCT Application No. PCT/JP2022/005126, filed Feb. 9, 2022 and based upon and claiming the benefit of priority from Japanese Patent Application No. 2021-024456, filed Feb. 18, 2021, the entire contents of all of which are incorporated herein by reference.

### FIELD

Embodiments described herein relate generally to a display device.

### BACKGROUND

Recently, display devices in which an organic light emitting diode (OLEDs) is applied as a display element have been put to practical use. The display devices comprise an organic layer between a pixel electrode and a common electrode. The organic layer includes a hole transport layer, an electron transport layer and other functional layers in addition to the light emitting layer.

As the display devices to which such display elements are applied become higher in resolution, the number of display elements increases and the number of apertures for connecting to the pixel circuits for driving and controlling the display elements also increases, which in turn reduces the area in which the organic layer can be placed. If the area where the organic layer can be placed is reduced, the light emitting area is reduced, resulting in a decrease in the brightness of the display device. Thus, it may lead to a decrease in the display quality.

### BRIEF DESCRIPTION OF THE DRAWINGS

FIG. 1 is a diagram showing a configuration example of a display device according to the first embodiment.

FIG. 2 is a plan view showing an example of a pixel shown in FIG. 1.

FIG. 3 is a plan view showing another example of a pixel shown in FIG. 1.

FIG. 4 is a cross-sectional view showing example of a display element according to the embodiment.

FIG. 5 is a cross-sectional view showing an example of a display element according to a comparative example.

FIG. 6 is a diagram showing an example of a display element according to the second embodiment.

FIG. 7A is a diagram illustrating a formation process of a cross-sectional configuration shown in FIG. 6.

FIG. 7B is a diagram illustrating a formation process of the cross-sectional configuration shown in FIG. 6.

FIG. 7C is a diagram illustrating a formation process of the cross-sectional configuration shown in FIG. 6.

FIG. 7D is a diagram illustrating a formation process of the cross-sectional configuration shown in FIG. 6.

FIG. 8 is a cross-sectional view showing a modified example of the display element according to the embodiment.

FIG. 9 is a cross-sectional view showing another modified example of the display element according to the embodiment.

### DETAILED DESCRIPTION

In general, according to one embodiment, a display device comprises a base, a plurality of pixel circuits, an insulating layer, a plurality of apertures, a plurality of display elements and a partition. The plurality of pixel circuits are disposed on the base. The insulating layer covers the base and each of the pixel circuits. The plurality of apertures are formed in the insulating layer, at respective locations overlapping of the pixel circuits. The plurality of display elements are driven and controlled respectively by the pixel circuits. The partition is disposed on the insulating layer to partition the display elements from each other. Each of the display elements comprises a lower electrode, an organic layer and an upper electrode. The lower electrode is disposed above the insulating layer and connected to the pixel circuit through the aperture. The organic layer is disposed in the aperture and covering the lower electrode. The upper electrode covers the organic layer. The lower electrode and the organic layer are in contact over an entire surface of the aperture. The organic layer and the upper electrode are in contact over the entire surface of the aperture. The peripheral portion of the lower electrode is covered by the partition.

According to another embodiment, a display device comprises a base, a plurality of pixel circuits, an insulating layer, a plurality of apertures and a plurality of display elements. The plurality of pixel circuits are disposed on the base. The insulating layer covers the base and each of the pixel circuits. The plurality of apertures are formed in the insulating layer, at respective locations overlapping of the pixel circuits. The plurality of display elements are driven and controlled respectively by the pixel circuits. Each of the display elements comprises a lower electrode, an organic layer and an upper electrode. The lower electrode is disposed above the insulating layer and connected to the respective pixel circuit through the aperture. The organic layer is disposed in the aperture and covering the lower electrode. The upper electrode covers the organic layer. The lower electrode and the organic layer are in contact over an entire surface of the aperture. The organic layer and the upper electrode are in contact over the entire surface of the aperture.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as an X direction or a first direction, a direction along the Y axis is referred to as a Y direction or a second direction and direction along the Z axis is referred to as a Z direction or a third direction. A plane defined by the X axis and the Y axis is referred to as an X-Y plane, and a plane defined by the X axis and the Z axis is referred to as an X-Z plane. Further, viewing towards the X-Y plane is referred to as plan view. Note that in a direction along the Z axis, the direction on the viewer's side is referred to as up or above, and the plane on the upper direction is referred to as an upper surface.

Display devices DSP of some embodiments are organic electroluminescent display device comprising an organic light emitting diode as a display element, and can be used in, for example, TV receivers, personal computers, mobile terminals, mobile telephones and the like. The display elements, which will be descried below, can be applied as light emitting display elements of illumination devices, and the display devices DSP can be converted into other electronic devices such as illumination devices and the like.

### First Embodiment

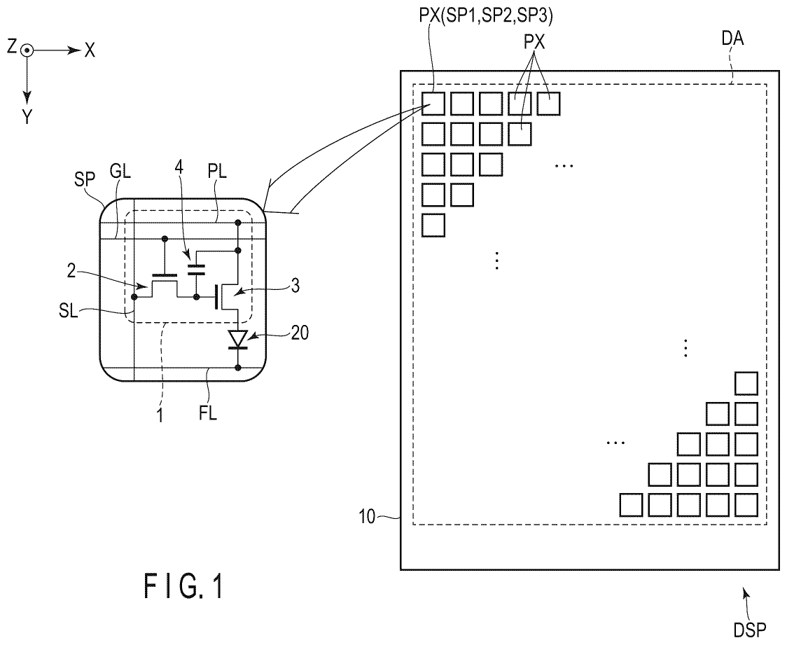

FIG. 1 is a diagram showing a configuration example of a display device DSP according to this embodiment. The display device DSP comprises a display area DA that displays images on an insulating base 10. The base 10 may be glass or a flexible resin film.

The display area DA comprises a plurality of pixels PX arranged in a matrix along the first direction X and the second direction Y. Each of the pixels PX comprises a plurality of subpixels SP1, SP2 and SP3. For example, the pixel PX comprises a red subpixel SP1, a green subpixel SP2 and a blue subpixel SP3. Note that in addition to the above three-color subpixels, the pixels PX may comprise four or more subpixels of other colors, such as white and the like.

A configuration example of one subpixel SP contained in a pixel PX will be briefly described.

The subpixel SP comprises a pixel circuit 1 and a display element 20 driven and controlled by the pixel circuit 1. The pixel circuit 1 comprises a pixel switch 2, a drive transistor 3 and a capacitor 4. The pixel switch 2 and the drive transistor 3 are switch elements constituted by thin-film transistors (TFT), for example.

In the pixel switch 2, a gate electrode is connected to a respective scanning line GL, a source electrode is connected to a respective signal line SL, and a drain electrode is connected to one of electrodes that constitute the capacitor 4 and a gate electrode of the drive transistor 3. In the drive transistor 3, a source electrode is connected to the other electrode of the capacitor 4 and a power line PL, and a drain electrode is connected to an anode of the display element 20. A cathode of the display element 20 is connected to a feeder line FL. Note that the configuration of the pixel circuit 1 is not limited to that of the example shown in the figure.

The display element 20 is an organic light emitting diode (OLED), which is a light emitting element. For example, the subpixel SP1 comprises a display element that emits light corresponding to red wavelengths, the subpixel SP2 comprises a display element that emits light corresponding to green wavelengths, and the subpixel SP3 comprises a display element that emits light corresponding to blue wavelengths. With the pixel PX comprising a plurality of subpixels SP1, SP2 and SP3 of display colors different from each other, a multicolor display can be realized.

Note here that the display elements 20 of the subpixels SP1, SP2 and SP3 may be configured to emit light of the same color. With this configuration, it is possible to realize monochromatic display.

Further, when the display elements 20 of the subpixels SP1, SP2 and SP3 are configured to emit white light, color filters may be arranged to oppose the display elements 20. For example, the subpixel SP1 comprises a red color filter opposing the display element 20, the subpixel SP2 comprises a green color filter opposing the display element 20, and the subpixel SP3 comprises a blue color filter opposing the display element 20. Thus, multicolor display can be realized.

Alternatively, when the display elements 20 of the subpixels SP1, SP2 and SP3 are configured to emit ultraviolet light, multicolor display can be realized by disposing light conversion layers to respectively oppose the display elements 20.

The configuration of the display element 20 will be described later.

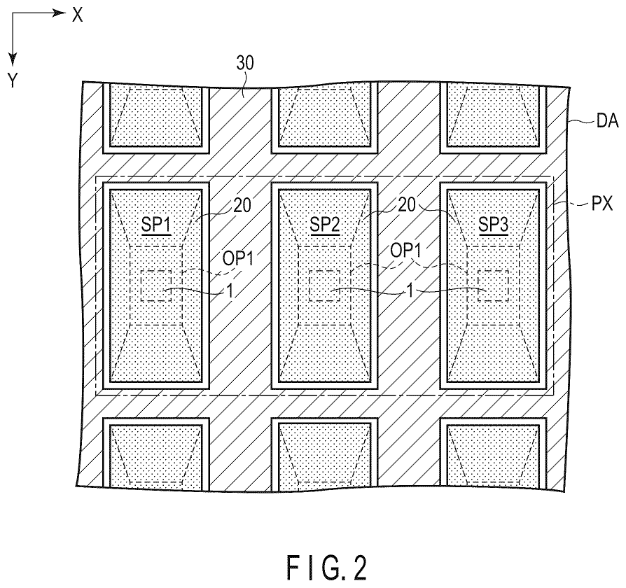

FIG. 2 is a plan view showing an example of the pixel PX shown in FIG. 1.

The subpixels SP1, SP2 and SP3, which constitute one pixel PX, are each formed into approximately a rectangular shape each extending in the second direction Y and aligned along the first direction X in the display area DA.

The display elements 20 included in the subpixels SP1, SP2 and SP3, respectively, are connected to the pixel circuits 1 included in the subpixels SP1, SP2 and SP3 through an aperture OP1, respectively. The aperture OP1 should desirably be formed so that the centers of the subpixels SP1, SP2, and SP3 are aligned at the centers of the apertures OP1, respectively. According to this, it is possible to provide a light emitting area, which will be described in detail later, to spread out from the center of each of the subpixels SP1, SP2 and SP3. The size of the aperture OP1 (the area in the X-Y plane) is not limited to that shown in the figure, but may be any size, for example, a size approximately the same as that of as the display element 20.

A partition 30, which will be described in detail later, is formed into a grid pattern extending in the first direction X and the second direction Y, respectively, in plan view, and surrounds each of the subpixels SP1, SP2 and SP3. The partition 30 may be referred to as a rib.

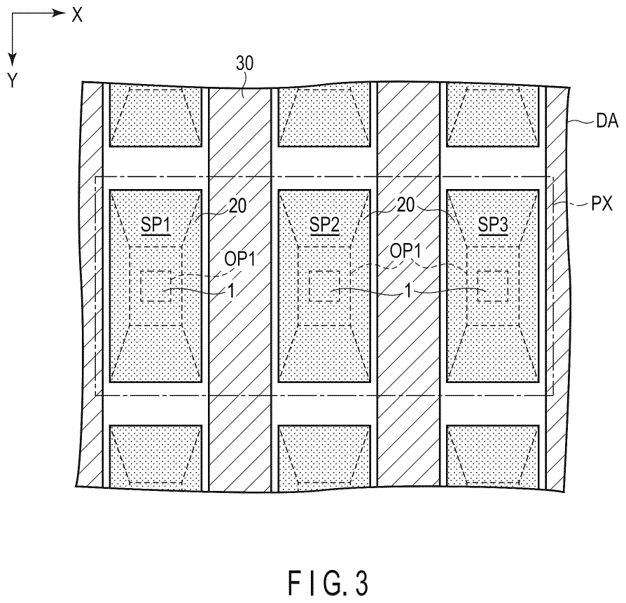

FIG. 3 is a plan view of another example of the pixel PX shown in FIG. 1.

The example shown in FIG. 3 differs from that of FIG. 2 in that the partitions 30 are formed into stripes. The partitions 30 each extend in the second direction Y and are aligned along the first direction X. Each of the subpixels SP1, SP2 and SP3 is located between a respective adjacent pair of partitions 30. In other words, the subpixels and the partitions are alternately arranged along the first direction X.

Note that in FIGS. 2 and 3, the rectangular-shaped subpixels SP1, SP2 and SP3 are shown as an example, but the shape of the subpixels SP1, SP2 and SP3 is not limited thereto. The subpixels SP1, SP2 and SP3 may be any shape different from a rectangular shape, such as any polygonal shape, circular shape, odd shape, etc. Further, the subpixels SP1, SP2 and SP3 may have shapes different from each other.

Further, in FIGS. 2 and 3, the case where the subpixels SP1, SP2 and SP3 are arranged into a stripe mode is illustrated. Here, the arrangement mode of the subpixels SP1, SP2 and SP3 is not limited to this, but the subpixels SP1, SP2 and SP3 may as well be arranged in a pen-tile mode, for example.

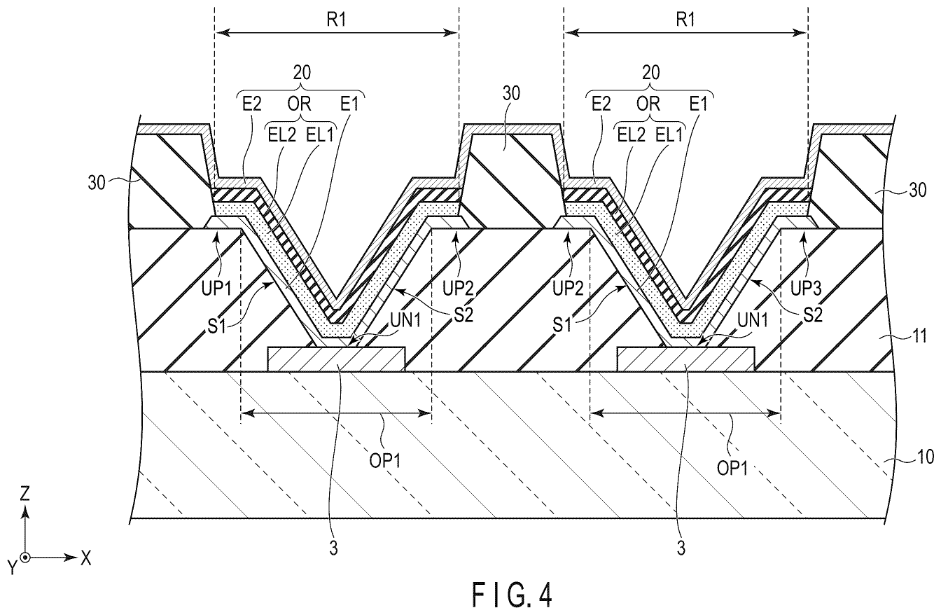

FIG. 4 is a cross-sectional view of an example of the display element 20 according to the embodiment. Note that in FIG. 4, two display elements adjacent to each other along the first direction X are illustrated. Note that the configuration of the two display elements 20 shown in FIG. 4 is similar the one described above except that the emitting colors of the light emitting layers, which will be described later, are different.

The pixel circuit 1 shown in FIG. 1 is disposed on the base 10 and covered by an insulating layer 11. In FIG. 4, only the drive transistor 3 included in the pixel circuit 1 is shown in simplified form. The insulating layer 11 corresponds to an underlayer of the display element 20 and is formed of, for example, an insulating material such as polyimide, acrylic resin, silicon nitride (SiN), silicon oxide (SiO) or the like.

The display element 20 comprises a lower electrode E1, an organic layer OR, and an upper electrode E2.

The lower electrode E1 is an electrode arranged for each subpixel or each display element and is electrically connected to the drive transistor 3. The lower electrode E1 having such a configuration may as well be referred to as a pixel electrode, a reflective electrode, an anode or the like.

The upper electrode E2 is an electrode arranged for each subpixel or each display element, but is electrically connected to over a plurality of adjacent subpixels or display elements. The upper electrode E2 having such a configuration may be referred to as a common electrode, a counter electrode, a cathode or the like.

The lower electrode E1 is disposed on the insulating layer 11 and is connected to the drive transistor 3 through the aperture OP1 formed in the insulating layer 11. The aperture OP1 is a through hole formed in a region overlapping the drive transistor 3 and penetrating the insulating layer 11 to the drive transistor 3.

The lower electrode E1 is a transparent electrode formed of, for example, a transparent conductive material such as indium tin oxide (ITO) or indium zinc oxide (IZO). Note that the lower electrode E1 may be a metal electrode formed by a metal material such as silver (Ag), aluminum (Al), titanium (Ti), molybdenum (Mo) or tungsten (W). Note that the lower electrode E1 may as well be a stacked body of a transparent electrode and a metal electrode. For example, the lower electrode E1 may as well be configured as a stacked body of a transparent electrode, a metal electrode and a transparent electrode, stacked in this order, or it may be configured as a stacked body of three or more layers.

The partition 30 is provided on the insulating layer 11 to cover the peripheral portion (edge portion) of the lower electrode E1. By covering the peripheral portion of the lower electrode E1 by the partition 30, it is possible to prevent the lower electrode E1 and the upper electrode E2 from coming into contact with each other and short-circuiting. The aperture OP1 is each located between a respective adjacent pair of partitions 30.

The organic layer OR is disposed on the lower electrode E1. In other words, the organic layer OR is disposed in the aperture OP1 and covers the lower electrode E1. The organic layer OR having such a configuration includes a first electro luminescent (EL) layer EL1 (a first organic layer). In the example shown in FIG. 4, the organic layer OR further includes a second EL layer EL2 (a second organic layer). The first EL layer EL1 and the second EL layer EL2 are stacked in order from the lower electrode E1 side.

The first EL layer EL1 includes a light-emitting layer that emits light in one of the colors red, green and blue, and functional layers. The functional layers included in the first EL layer EL1 are, for example, a hole injection layer, a hole transport layer, an electron blocking layer and the like, but may be other functional layers. The second EL layer EL2 includes functional layers. The functional layers included in the second EL layer EL2 are, for example, a hole blocking layer, an electron transport layer, an electron injection layer and the like, but may be other functional layers. Each of the first EL layer EL1 and the second EL layer EL2 illustrated in the drawings is not limited to a single layer, but may be a stacked body in which a plurality of layers are stacked. In this case, the layers located further lower may be formed smaller and the lower layer may be covered by an upper layer located above the lower layer. Further, some of the functional layers in the first EL layer EL1 and the second EL layer EL2 may be omitted.

The upper electrode E2 covers the organic layers OR and the partitions 30. The upper electrode E2 is a common layer commonly used over the plurality of display elements 20. The upper electrode E2 is a transparent electrode formed of, for example, a transparent conductive material such as ITO or IZO. Note that the upper electrode E2 may as well be a semi-transparent metal electrode formed of a metal material such as magnesium (Mg), silver (Ag), aluminum (Al) or the like. The upper electrode E2 is electrically connected to a feeder line located in the display area DA or on an outer side of the display area DA.

When the potential of the lower electrode E1 is relatively higher than that of the upper electrode E2, the lower electrode E1 corresponds to the anode and the upper electrode E2 corresponds to the cathode. Further, when the potential of the upper electrode E2 is relatively higher than that of the lower electrode E1, the upper electrode E2 corresponds to the anode and the lower electrode E1 corresponds to the cathode.

In this embodiment, the case where the lower electrode E1 corresponds to the anode and the upper electrode E2 corresponds to the cathode is assumed as an example. Therefore, the functional layers included in the first EL layer EL1 include at least one of the hole injection layer, the hole transport layer and the electron blocking layer, and the functional layers contained in the second EL layer EL2 include at least one of the hole blocking layer, the electron transport layer and the electron injection layer.

According to the configuration shown in FIG. 4, the light emitting area of the display element can be formed in the portion where the organic layer OR is disposed, which is located between the lower electrode E1 disposed in the aperture OP1 and the upper electrode E2 disposed as a common layer. In other words, the light emitting area of the display element can be formed in a region R1 including an under surface UN1 of the aperture OP1, slopes S1 and S2 of the aperture OP1 and a part of each of the upper surfaces UP1 and UP2 of the insulating layer 11.

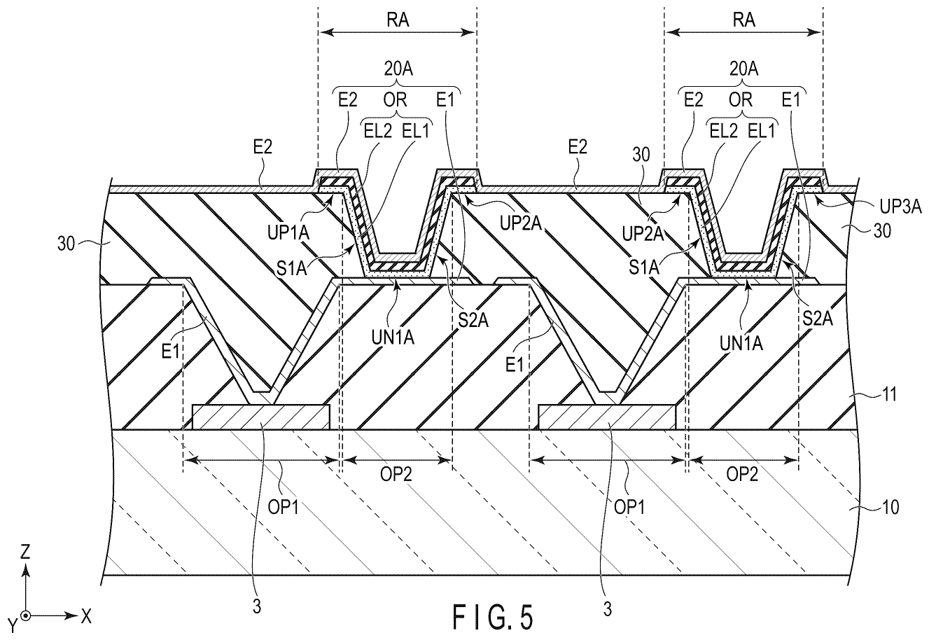

Here, the advantageous effects of this embodiment will now be explained by utilizing a comparative example shown in FIG. 5. Note that the comparative example is provided to illustrate some of the effects that can be exhibited by this embodiment, and does not exclude from the scope of the present invention the effects common to the comparative example and the present embodiment.

A display element 20A in the comparative example differs from display element 20 of the present embodiment in that, as shown in FIG. 5, an organic layer OR is not disposed in the aperture OP1 for connecting the lower electrode E1 and the drive transistor 3, but a partition 30 is disposed, and the organic layer OR is disposed in an aperture OP2 located between two adjacent partitions 30.

In the display element 20A in the comparative example, as shown in FIG. 5, the organic layer OR is disposed through the aperture OP2 and connected to the lower electrode E1 exposed in the aperture OP2. Therefore, in the display element 20A in the comparative example, a light emitting area is formed in a region RA including an under surface UN1A of the aperture OP2, slopes S1A and S2A of the aperture OP2 and a part of the upper surfaces UP1A and UP2A of the partition 30.

However, in the slopes S1A and S2A of the aperture OP2 and the part of the upper surfaces UP1A and UP2A of the partition 30, the partition 30 is interposed between the lower electrode E1 and the upper electrode E2. Therefore, such a problem is created that light is not substantially emitted from a part of the organic layer OR that is disposed in the slopes S1A and S2A of the aperture OP2 and the part of the upper surfaces UP1A and UP2A of the partition 30.

In contrast, in the display element 20 of this embodiment, as shown in FIG. 4, there is no portion where the layers other than the organic layer OR are interposed between the lower electrode E1 and the upper electrode E2, located in the region R1, which is a light emitting area, and therefore the organic layer OR can be made to emit light in the entire light emitting area.

Further, in the display device in which the display element 20A in the comparative example are provided, as the resolution is higher, the number of apertures OP1 for connecting the lower electrode E1 and the drive transistor 3 increases. As a result, the portion where the partitions 30 are disposed increases, and therefore the area of the aperture OP2 located between two adjacent partitions 30 become narrower. Thus, the light emitting area of the display element may become undesirably smaller. Consequently, the luminance thereof is decreased, which makes displayed images to be darker. Thus, such a problem occurs that the display quality of the display device may be damaged.

By contrast, in the display element 20 of this embodiment, the entire surface of the aperture OP1 for connecting the lower electrode E1 and the drive transistor 3 can be made into a light emitting area. With this structure even if the number of apertures OP1 increases as the resolution of the display device DSP in which the display elements 20 are installed becomes higher, the light emitting area of the display element is not decreased, thus making it possible to suppress the lowering in luminance associated with higher resolution described above and to suppress the degradation in display quality.

According to the first embodiment described above, the display device DSP comprises a plurality of subpixels SP (pixels PX) each including the display element 20 in which the aperture OP1 for connecting the lower electrode E1 and the drive transistor 3 as the light emitting area. According to this configuration, if the resolution of the display device DSP becomes higher, the light emitting area of the display element is not decreased and a sufficient light emitting area can be secured, thereby suppressing the lowering in luminance associated with the higher resolution and the degradation in display quality.

### Second Embodiment

Next, the second embodiment will be described. A display device DSP of the second embodiment differs from the first embodiment described above in that no partition 30 is provided to partition an organic layer OR included in a display element 20. Note that in this embodiment, the description of the configuration common to the above-described first embodiment will be omitted, and the points that differ from those of the above-described first embodiment will be mainly described.

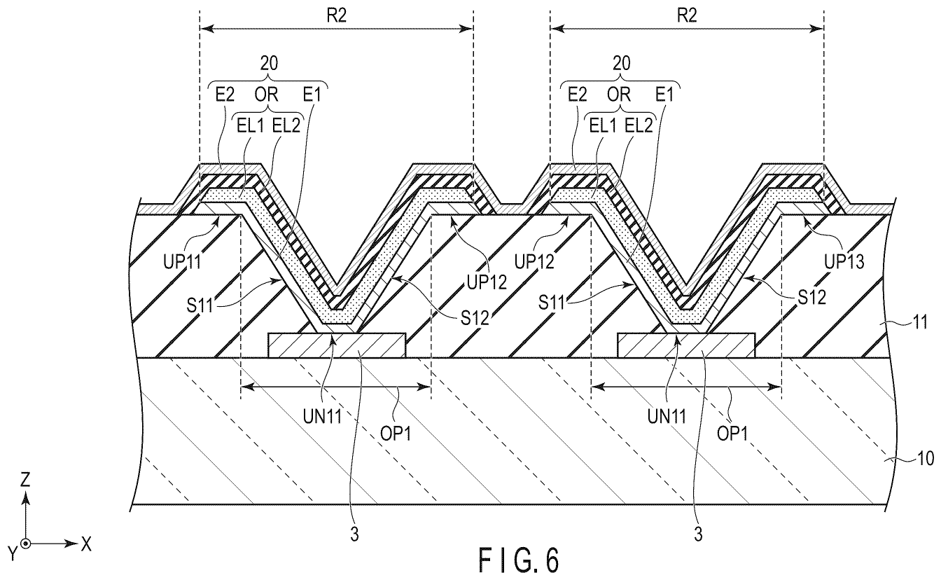

FIG. 6 is a cross-sectional view of example of display elements 20 according to this embodiment. In FIG. 6, two display elements 20 adjacent to each other along the first direction X are illustrated. The configurations of the two display elements 20 shown in FIG. 6 are similar to each other except that the colors of the light emitted from the light emitting layers are different from each other. Further, in FIG. 6, only the drive transistor 3 included in the pixel circuit 1 is shown in a simplified form.

As shown in FIG. 6, the drive transistor 3 is disposed on the base 10 and covered by the insulating layer 11. The lower electrode E1, which constitutes the display element 20, is connected to the drive transistor 3 through the aperture OP1 formed in the insulating layer 11. Note that as shown in FIG. 6, the peripheral portion of the lower electrode E1 is formed into a forward tapered shape.

The organic layer OR, which constitutes the display element 20, is placed in the aperture OP1 and covers the lower electrode E1. As in the first embodiment described above, the organic layer OR includes the first EL layer EL1 including a light-emitting layer and a functional layer, and the second EL layer EL2 including a functional layer. Note that as shown in FIG. 6, the peripheral portion of each of the first EL layer EL1 and the second EL layer EL2 are formed into a forward tapered shape, unlike in the first embodiment described above.

As shown in FIG. 6, the peripheral portion of the lower electrode E1 and the peripheral portion of the first EL layer EL1 are covered by the second EL layer EL2. With this configuration, it is possible to prevent the lower electrode E1 and the upper electrode E2 from coming into contact with each other and short-circuiting. Note that FIG. 6 shows the case where the peripheral portion of the lower electrode E1 and the peripheral portion of the first EL layer EL1 are aligned on the same diagonal line. It should be noted here that the peripheral portion of the lower electrode E1 and the peripheral portion of the first EL layer EL1 may not necessarily be aligned on the same diagonal line, but the peripheral portion of the first EL layer EL1 may cover a part of the peripheral portion of the lower electrode E1.

The upper electrode E2 covers the organic layer OR.

According to the configuration shown in FIG. 6, the light emitting area of the display element can be formed in the portion where the organic layer OR is located between the lower electrode E1 disposed in the aperture OP1 and the upper electrode E2 disposed as a common layer. In other words, in a region R2 including the under surface UN11 of the aperture OP1, the slopes S11 and S12 of the aperture OP1, and parts of the upper surfaces UP11 and UP12 of the insulating layer 11, the light emitting area of the display element 20 can be formed.

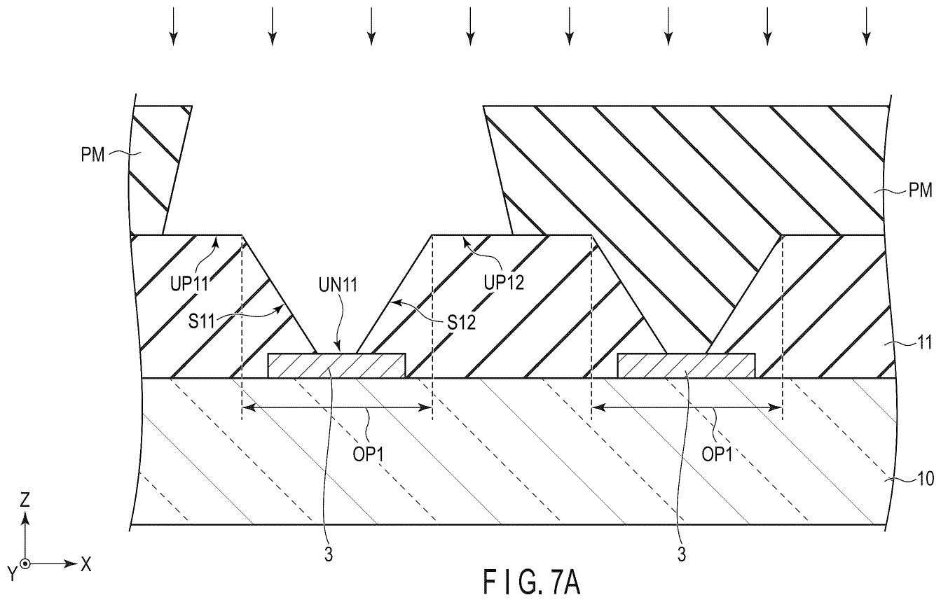

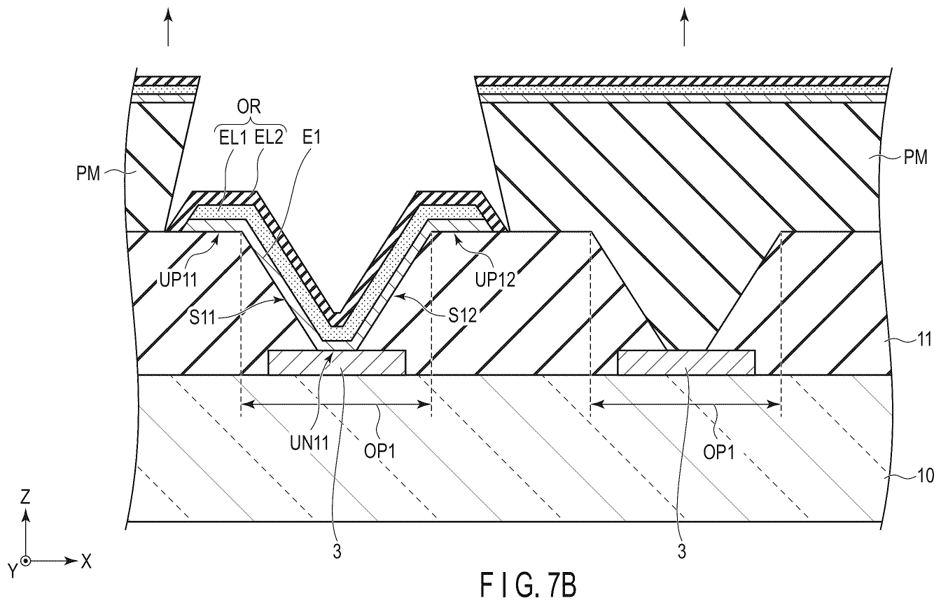

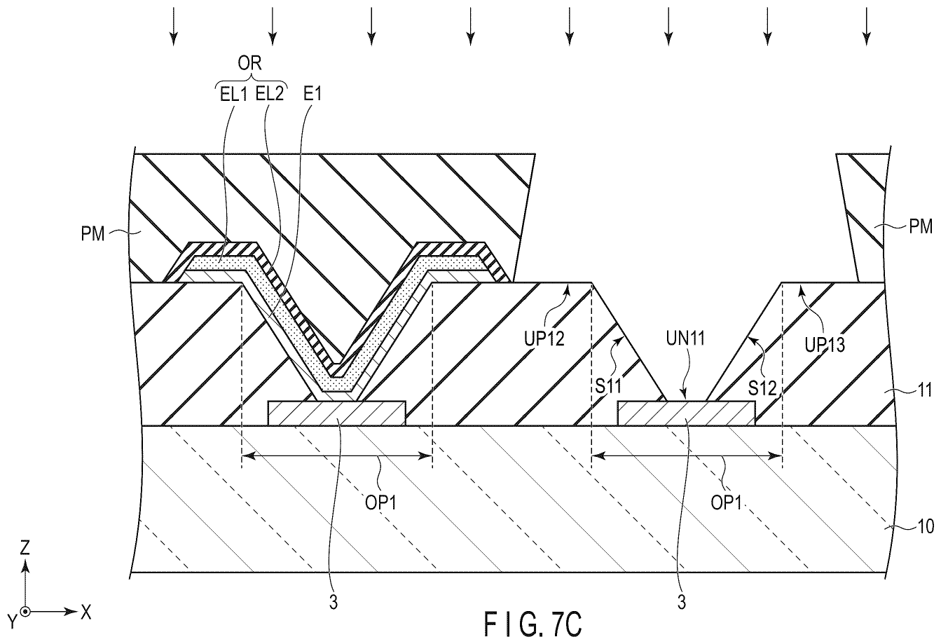

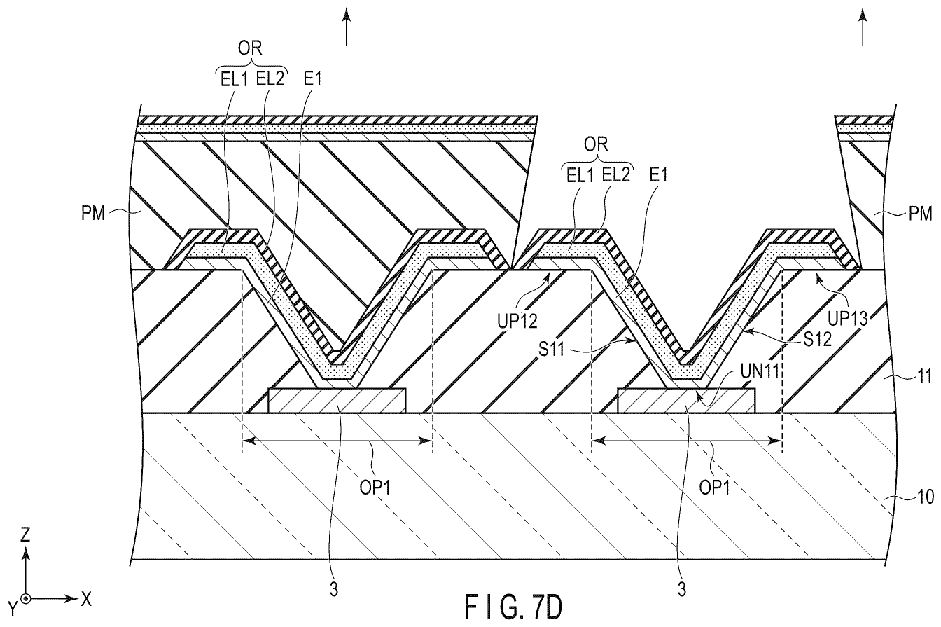

The display element 20 having the configuration shown in FIG. 6 can be formed, for example, by the formation processes shown in FIGS. 7A to 7D. FIGS. 7A to 7D are diagrams each illustrate a formation process for forming of the cross-sectional structure shown in FIG. 6.

First, the drive transistor 3 (pixel circuit 1) is provided on the base 10. Next, the insulating layer 11 is formed to cover the drive transistor 3 provided on the base 10. In a region of the insulating layer 11, which overlaps the drive transistor 3, the aperture OP1 is formed. Thus, the surface of the drive transistor 3 is exposed from the insulating layer 11.

Then, a reverse tapered mask PM is provided in the area other than the area where the display element 20 of a predetermined color (for example, one of red, green and blue, that is, hereinafter referred to as the first color) is placed. For example, as shown in FIG. 7A, the reverse tapered shape mask PM is provided in the area other than the under surface UN11 of the aperture OP1, the slopes S11 and S12 of the aperture OP1, and part of the upper surfaces UP11 and UP12 of the insulating layer 11 on the left-hand side in the figure, where the display element 20 of the first color is placed.

Next, a layer structure other than the common layer, that is included in the first color display element 20 is formed. In this case, as shown in FIG. 7B, the lower electrode E1, the first EL layer EL1 and the second EL layer EL2 are formed in this order. As described above, the reverse tapered mask PM is provided in the area other than the bottom surface UN11 of the aperture OP1, the slopes S11 and S12 of the aperture OP1 and part of the upper surfaces UP11 and UP12 of the insulating layer 11, on the left hand side of the figure, where the first color display element 20 is placed. Therefore the peripheral portion of the lower electrode E1 formed in the aperture OP1, the peripheral portion of the first EL layer EL1 and the peripheral portion of the second EL layer EL2 are each formed in a forward tapered shape.

Note that the second EL layer EL2 is formed over a wider area than those of the lower electrode E1 and the first EL layer EL1. According to this configuration, as shown in FIG. 7B, the peripheral portion of the lower electrode E1 formed in the aperture OP1 and the peripheral portion of the first EL layer EL1 can be covered by the second EL layer EL2.

When the layer structure other than the common layer included in the display element 20 of the first color is formed, the mask PM is removed. As a result, the lower electrode E1, the first EL layer EL1 including the emitting layer of the first color and the second EL layer EL2 are placed only in the aperture OP1 on the left hand side in the figure. More specifically, the lower electrode E1, the first EL layer EL1 including the light emitting layer of the first color and the second EL layer EL2 are disposed in the portions which overlap the under surface UN11 of the aperture OP1, the slopes S11 and S12 of the aperture OP1, and part of the upper surfaces UP11 and UP12 of the insulation layer 11, on the left hand side in the figure.

Subsequently, the reverse tapered mask PM is provided in the area other than the area where the display element 20 of a predetermined color different from the first color described above(, that is, one of red, green and blue and different from the first color, hereinafter to be referred to as the second color) is placed. For example, as shown in FIG. 7C, the reverse tapered shape mask PM is provided in the area other than the under surface UN11 of the aperture OP1, the slopes S11 and S12 of the aperture OP1 and part of the upper surfaces UP12 and UP13 of the insulating layer 11 on the right hand side in the figure, where the display element 20 of the second color is placed.

Thereafter, a layer structure other than the common layer included in the display element 20 of the second color is formed. In this case, as shown in FIG. 7D, the lower electrode E1, the first EL layer EL1 and the second EL layer EL2 are formed in order in the aperture OP1 on the right hand side of the figure. As in the case of the configuration shown in FIG. 7B, the reverse tapered mask PM is provided in the area other than the under surface UN11 of the aperture OP1 on the right side of the figure where the display element 20 of the second color is placed, the slopes S11 and S12 of the aperture OP1 and part of the upper surfaces UP12 and UP13 of the insulating layer 11. With this configuration, the peripheral portion of the lower electrode E1, the peripheral portion of the first EL layer EL1 and the peripheral portion of the second EL layer EL2 formed in the aperture OP1 on the right hand side of the figure are each formed into a forward tapered shape.

When the layer structure other than the common layer included in the display element 20 of the second color is formed, the mask PM is removed. As a result, in the aperture OP1 on the right hand side of the figure, as well, the lower electrode E1, the first EL layer EL1 including the light-emitting layer of the second color and the second EL layer EL2 are disposed. More specifically, in the portions overlapping the lower surface UN11 of the aperture OP1, the slopes S11 and S12 of the aperture OP1 and part of the upper surface UP12 and UP13 of the insulation layer 11 on the right hand side of the figure, the lower electrode E1, the first EL layer EL1 including the light emitting layer of the second color and the second EL layer EL2 are disposed.

Although a detailed description is omitted here, the formation process shown in FIGS. 7A to 7D described above is repeated for the display element 20 of a different color from the first color and the second color. As a result, the layer structure other than the common layer included in the display element (that is, the lower electrode E1, the first EL layer EL1 and the second EL layer EL2) is formed in all of the apertures OP1 formed in the insulating layer 11.

After that, the upper electrode E2, which is included in the display element 20 as a common layer, is formed over the entire surface of the insulating layer 11 so as to cover the insulating layer 11 and the second EL layer EL2 (organic layer OR). As a result, a display element 20 having the cross-sectional structure shown in FIG. 6 is formed.

In the series of formation processes shown in FIGS. 7A to 7D, the lower electrode E1, the first EL layer EL1 and the second EL layer EL2, which are layers other than the common layer included in the display element 20, are formed using the reverse tapered shape mask PM. Therefore, as described above, the peripheral portion of the lower electrode E1, the peripheral portion of the first EL layer EL1 and the peripheral portion of the second EL layer EL2 can be each formed into a forward tapered shape.

In the general patterning method, the peripheral portions of the lower electrode E1, the first EL layer EL1 and the second EL layer EL2 are all formed substantially vertically. With this configuration, when the upper electrode E2 is formed on top of the second EL layer EL2, the upper electrode E2 may be cut off.

By contrast, in this embodiment, as described above, by using the reverse tapered mask PM, the peripheral portions of the lower electrode E1, the first EL layer EL1 and the second EL layer EL2 can be made into a forward tapered shape. Therefore, the risk that the upper electrode E2 is cut off, which may occur when the upper electrode E2 is formed on the second EL layer EL2, can be reduced.

In the series of the formation processes shown in FIGS. 7A to 7D, with use of the reverse tapered mask PM, it is possible to form the peripheral portion of the lower electrode E1, the peripheral portion of the first EL layer EL1 and the peripheral portion of the second EL layer EL2 each into a forward tapered shape, as described above, and with the second EL layer EL2, at least the peripheral portion of the lower electrode E1 can covered by the second EL layer EL2 without the second EL layer EL2 being cut off. According to this configuration, it is no longer necessary to provide the partition 30 to prevent the lower electrode E1 and the upper electrode E2 from coming into contact with each other. In other words, the process of providing the partition 30 can be omitted and the manufacturing cost can be reduced to the extent that the partition 30 is omitted.

Further, according to the configuration of the second embodiment, in a display element 20, the lower electrode E1, the first EL layer EL1 and the second EL layer EL2, which are disposed on the upper surface UP of the insulating layer 11, can be extended toward an adjacent display element 20 to the extent that there is no partition 30 provided. In other words, it is possible to expand the light emitting area of the display element 20 as compared to the case of the first embodiment described above.

According to the second embodiment described above, not only effects similar to those of the first embodiment described above can be obtained, but it is also possible to omit the process of providing the partition 30. Therefore, the manufacturing cost can be reduced, and the light emitting area of the display element 20 can be further expanded.

Modified examples of this embodiment will be described below.

### First Modified Example

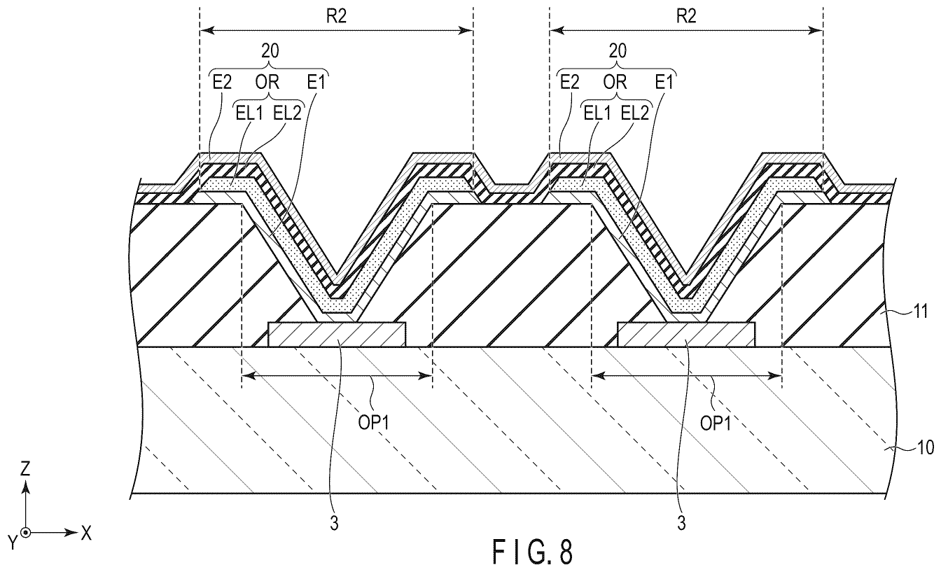

FIG. 8 is a cross-sectional view of an example of the display element 20 of the first modified example of this embodiment. In FIG. 8, two display elements 20 adjacent to each other along the first direction X are illustrated. The configurations of the two display elements 20 shown in FIG. 8 are similar to each other except that the colors of light emitted from the light emitting layer s are different. Further, in FIG. 8, only the drive transistor 3 included in the pixel circuit 1 is shown in a simplified form.

The display element 20 of the first modified example differs in configuration from that shown in FIG. 6, that is, more specifically in that the second EL layer EL2 included in the organic layer OR is not provided for each of the display elements 20, but is provided as a common layer used over a plurality of display elements 20, as shown in FIG. 8.

In this case as well, with use of the reverse tapered mask PM, it possible as described before to form the peripheral portion of the lower electrode E1 and the peripheral portion of the first EL layer EL1 in a forward tapered shape, and thus at least the peripheral portion of the lower electrode E1 can be covered by the second EL layer EL2 without the second EL layer EL2 being cut off. That is, it is possible to omit the partition 30, which is provided for preventing the lower electrode E1 and the upper electrode E2 from coming into contact with each other, advantageous effects similar to those of the second embodiment described above can be obtained by the configuration according to this modified example.

### Second Modified Example

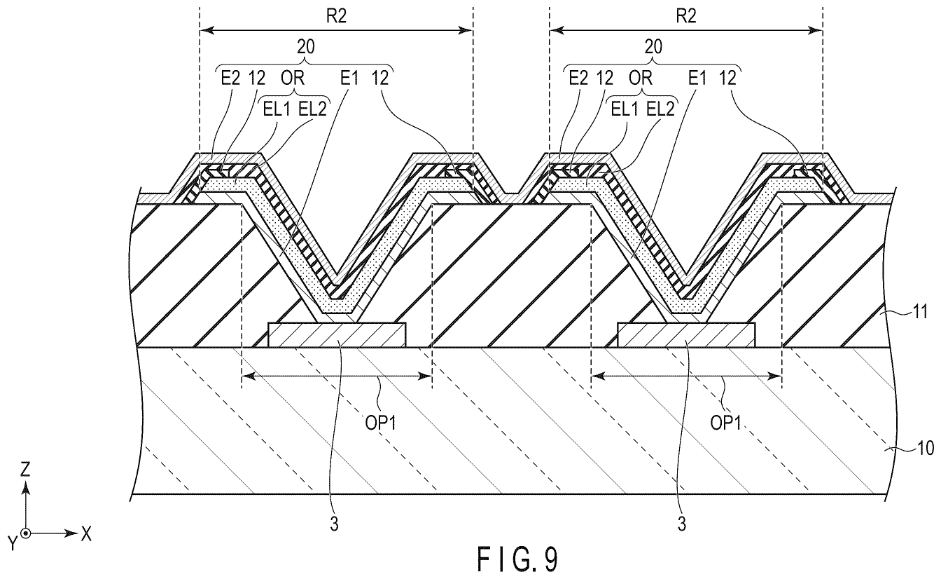

FIG. 9 is a cross-sectional view of an example of the display element 20 according to the second modified example of this embodiment. In FIG. 9, two display elements 20 adjacent to each other along the first direction X are illustrated. The configurations of the two display elements 20 shown in FIG. 9 are similar to each other except that the colors of light emitted by the light emitting layers are different. Further, in FIG. 9, only the drive transistor 3 included in the pixel circuit 1 is shown in a simplified form.

The display element 20 of the second modified example differs in configuration from that shown in FIG. 6, more specifically, in that it further comprises an insulating film 12 that covers the peripheral portion of the lower electrode E1 and the peripheral portion of the first EL layer EL1 included in the organic layer OR, and further that is covered by the second EL layer EL2 included in the organic layer OR as shown in FIG. 9. Note that the insulating film 12 should be provided to at least cover the peripheral portion of the lower electrode E1.

The insulating film 12 is formed of, for example, an insulating material such as silicon nitride (SiN) and is provided to prevent the lower electrode E1 and the upper electrode E2 from coming into contact with each other and shorting-circuiting. In the configuration according to this modified example, it is necessary to provide the insulating film 12 in place of the partition 30, but the insulating film 12 need only be provided in a smaller area as compared to the case of the partition 30. Therefore, the light emitting area of the display element 20 can be expanded in a manner similar to that of the second embodiment described above. Note that the insulating film 12 of this modified example may as well be implemented by replacing it with a carrier blocking layer such as a hole blocking layer or an electron blocking layer.

According to at least one of the embodiments described above, it is possible to form the display element 20 with the aperture OP1 for connecting the lower electrode E1 and the drive transistor 3, which serves as the light emitting area, and thus possible to provide the display device DSP that can suppress the degradation in display quality.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a base;
a plurality of pixel circuits disposed on the base;
an insulating layer which covers the base and each of the pixel circuits;
a plurality of apertures formed in the insulating layer, at respective locations overlapping of the pixel circuits;
a plurality of display elements driven and controlled respectively by the pixel circuits; and
a partition disposed on the insulating layer to partition the display elements from each other,
wherein
each of the display elements comprises:
a lower electrode disposed above the insulating layer and connected to the pixel circuit through the aperture;
an organic layer disposed in the aperture and covering the lower electrode; and
an upper electrode covering the organic layer,
the lower electrode and the organic layer are in contact over an entire surface of the aperture,
the organic layer and the upper electrode are in contact over the entire surface of the aperture, and
a peripheral portion of the lower electrode is covered by the partition.

2. The display device of claim 1, wherein
the partition is formed into a grid pattern in plan view.

3. The display device of claim 1, wherein
the partition is formed into a stripe shape in plan view.

4. A display device comprising:
a base;
a plurality of pixel circuits disposed on the base;
an insulating layer which covers the base and each of the pixel circuits;
a plurality of apertures formed in the insulating layer, at respective locations overlapping of the pixel circuits; and
a plurality of display elements driven and controlled respectively by the pixel circuits,
wherein
each of the display elements comprises:
a lower electrode disposed above the insulating layer and connected to the respective pixel circuit through the aperture;
an organic layer disposed in the aperture and covering the lower electrode; and
an upper electrode covering the organic layer,
the lower electrode and the organic layer are in contact over an entire surface of the aperture, and
the organic layer and the upper electrode are in contact over the entire surface of the aperture.

5. The display device of claim 4, wherein
a peripheral portion of the lower electrode is covered by the organic layer, and the lower electrode and the upper electrode are not in contact with each other.

6. The display device of claim 5, wherein
the organic layer includes at least a first organic layer and a second organic layer including at least one functional layer, and
the peripheral portion of the lower electrode, a peripheral portion of the first organic layer and a peripheral portion of the second organic layer each has a forward tapered shape.

7. The display device of claim 6, wherein
the peripheral portion of the lower electrode is covered by at least the peripheral portion of the second organic layer.

8. The display device of claim 7, wherein
the upper electrode is disposed over the plurality of display elements.

9. The display device of claim 8, wherein
the second organic layer is disposed over the plurality of display elements.

10. The display device of claim 4, further comprising:
an insulating film which covers the peripheral portion of the lower electrode and is covered by the organic layer,
wherein the lower electrode and the upper electrode are not in contact with each other.

11. The display device of claim 4, further comprising:
a carrier blocking layer which covers the peripheral portion of the lower electrode and is covered by the organic layer,
wherein the lower electrode and the upper electrode are not in contact with each other.

12. The display device of claim 11, wherein
the carrier blocking layer includes at least one of a hole blocking layer and an electron blocking layer.
